(19) United States
(12) Patent Application Publication
(10) Pub. No.: US 2025/0081334 A1
(43) Pub. Date: Mar. 6, 2025

(54) PRINTED WIRING BOARD

(71) Applicant: IBIDEN CO., LTD., Ogaki (JP)

(72) Inventor: Katsuyuki SANO, Ogaki (JP)

(73) Assignee: IBIDEN CO., LTD., Ogaki (JP)

(21) Appl. No.: 18/819,067

(22) Filed: Aug. 29, 2024

(30) Foreign Application Priority Data
Sep. 4, 2023 (JP) 2023-142697

(51) Int. Cl. H05K 1/02; H05K 1/11

(52) U.S. Cl. CPC H05K 1/0296; H05K 1/115; H05K 2201/2081

(57) ABSTRACT

A printed wiring board includes an uppermost resin insulating layer, an uppermost conductor layer, a solder resist layer, a dam conductor connected to the upper most conductor layer, and a metal dam formed on and connected to the dam conductor. The uppermost conductor layer includes electrodes and a conductor circuit that are positioned to mount an electronic component in a mounting area in the solder resist layer. The metal dam is surrounding the mounting area. The solder resist layer has first openings reaching to the electrodes of the uppermost conductor layer and a second opening reaching to the conductor circuit of the uppermost conductor layer. The dam conductor is formed in the second opening of the solder resist layer. The conductor circuit in the uppermost conductor layer is a ground circuit or power supply circuit such that the conductor circuit is connected to the metal dam via the dam conductor.

### CROSS-REFERENCE TO RELATED APPLICATIONS

The present application is based upon and claims the benefit of priority to Japanese Patent Application No. 2023-142697, filed Sep. 4, 2023, the entire contents of which are incorporated herein by reference.

### BACKGROUND OF THE INVENTION

### Field of the Invention

The present invention relates to a printed wiring board.

### Description of Background Art

Japanese Patent Application Laid-Open Publication No. 2014-96558 describes a printed wiring board having a base substrate and a dam formed on the base substrate. The entire contents of this publication are incorporated herein by reference.

### SUMMARY OF THE INVENTION

According to one aspect of the present invention, a printed wiring board includes an uppermost resin insulating layer, an uppermost conductor layer formed on the uppermost resin insulating layer, a solder resist layer formed on the uppermost resin insulating layer such that the solder resist layer is covering the uppermost conductor layer, a dam conductor formed in the solder resist layer such that the dam conductor is connected to the upper most conductor layer, and a metal dam formed on the solder resist layer such that the metal dam is formed on and connected to the dam conductor. The uppermost conductor layer includes electrodes and a conductor circuit such that the electrodes and conductor circuit are positioned to mount an electronic component in a mounting area in the solder resist layer and that the metal dam is surrounding the mounting area of the solder resist layer, the solder resist layer is formed such that the solder resist layer has first openings reaching to the electrodes of the uppermost conductor layer and a second opening reaching to the conductor circuit of the uppermost conductor layer and that the dam conductor is formed in the second opening of the solder resist layer, and the conductor circuit in the uppermost conductor layer is a ground circuit or a power supply circuit such that the conductor circuit is connected to the metal dam via the dam conductor.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view schematically illustrating a printed wiring board according to an embodiment of the present invention;

FIG. 2 is a cross-sectional view between II-II of FIG. 1;

FIG. 3 is a cross-sectional view between III-III of FIG. 1;

FIG. 4 is a cross-sectional view schematically illustrating a printed wiring board of an alternative example according to an embodiment of the present invention; and

FIG. 5 is a cross-sectional view schematically illustrating a printed wiring board of a modified example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Embodiment

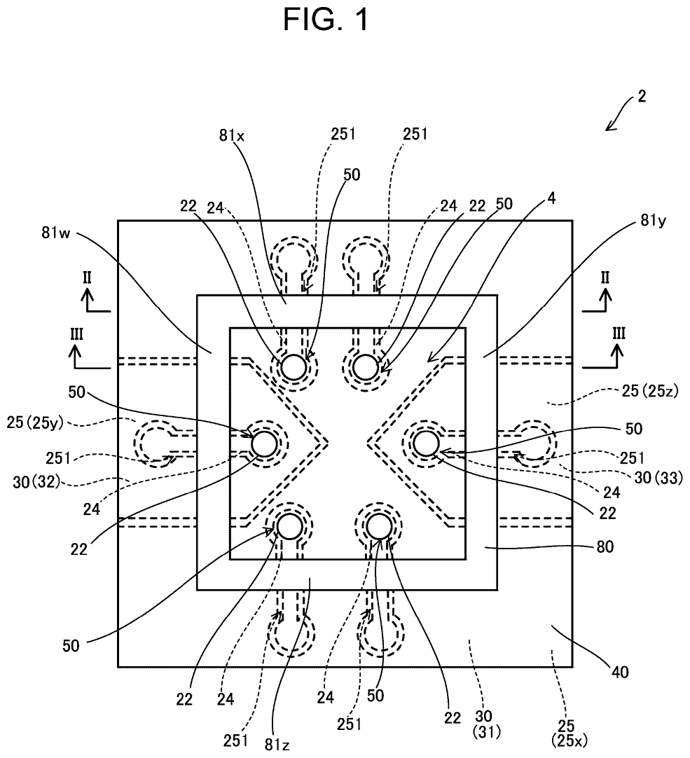

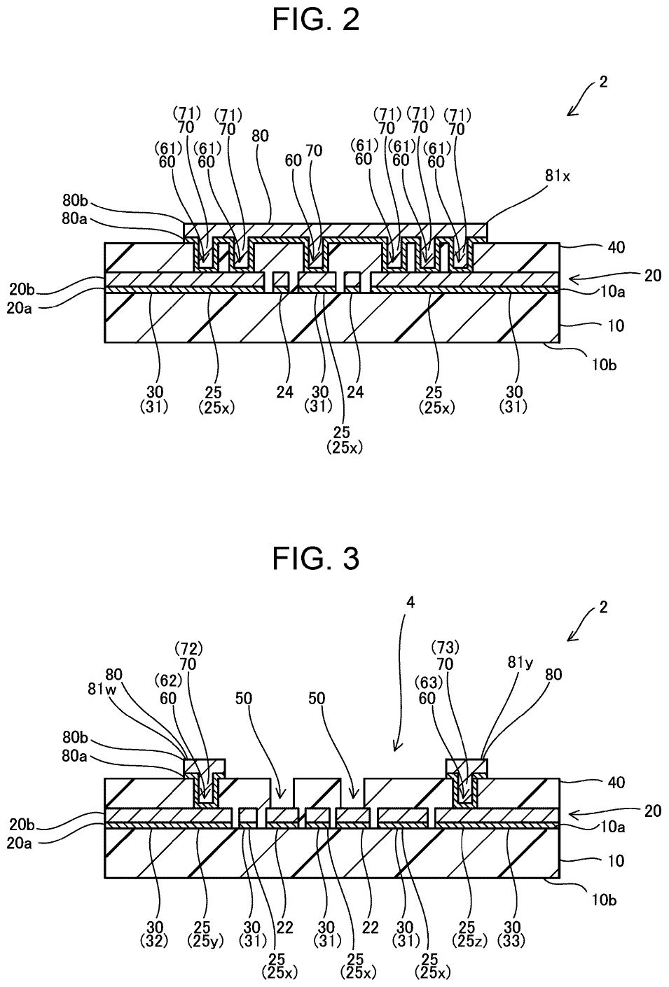

FIG. 1 is a plan view illustrating a printed wiring board 2 according to an embodiment of the present invention. FIG. 2 is a cross-sectional view between II-II of FIG. 1. FIG. 3 is a cross-sectional view between III-III of FIG. 1. As illustrated in FIGS. 1-3, the printed wiring board 2 has an uppermost resin insulating layer 10, an uppermost conductor layer 20, a solder resist layer 40 having openings (50, 60), dam conductors 70 formed in the openings 60, and a metal dam 80. The uppermost resin insulating layer 10 has a first surface (10a) and a second surface (10b) on the opposite side with respect to the first surface (10a). The uppermost conductor layer 20 is formed on the first surface (10a) of the resin insulating layer 10. The solder resist layer 40 is formed on the first surface (10a) of the uppermost resin insulating layer 10 and on the uppermost conductor layer 20. The printed wiring board 2 may have a core substrate under the uppermost resin insulating layer 10 and the uppermost conductor layer 20.

The resin insulating layer 10 is formed using a thermosetting resin. It is also possible that the material of the resin insulating layer 10 is a photocurable resin. The resin insulating layer 10 may contain inorganic particles such as silica particles. The resin insulating layer 10 may contain a reinforcing material such as a glass cloth.

The uppermost conductor layer 20 has multiple electrodes 22 and a conductor circuit 30 for mounting an electronic component. The uppermost conductor layer 20 is mainly formed of copper. The uppermost conductor layer 20 is formed of a seed layer (20a) and an electrolytic plating layer (20b) on the seed layer (20a). The seed layer (20a) is formed by electroless plating or sputtering. The electrolytic plating layer (20b) is formed by electrolytic plating. The uppermost conductor layer 20 may have signal wirings 24 in addition to the electrodes 22 and the conductor circuit 30. The electrodes 22 include signal electrodes, power supply electrodes, and ground electrodes. Examples of the conductor circuit 30 include a ground circuit and a power supply circuit. As a conductor circuit 30, the uppermost conductor layer 20 includes a power supply circuit. Or, as a conductor circuit 30, the uppermost conductor layer 20 includes a ground circuit. Or, as conductor circuits 30, the uppermost conductor layer 20 includes both a ground circuit and a power supply circuit. The uppermost conductor layer 20 may have conductor circuits 30 that have substantially the same potential. Conductor circuits 30 that have the same potential are referred to as equipotential circuits. When the uppermost conductor layer 20 has equipotential circuits, there are multiple such circuits. A first equipotential circuit is a first conductor circuit 31, a second equipotential circuit is a second conductor circuit 32, and a third equipotential circuit is a third conductor circuit 33. The signal wirings 24 are connected to one signal electrode. The power supply circuit is connected to at least one power supply electrode. It is preferable that one power supply circuit is connected to three or more power supply electrodes. The ground circuit is connected to at least one ground electrode. It is preferable that one ground circuit is connected to three or more ground electrodes.

The uppermost conductor layer 20 of the embodiment is depicted as a perspective view in FIG. 1. FIG. 1 illustrates only the signal electrodes, omitting the power supply electrodes and the ground electrodes. FIG. 1 depicts the electrodes 22, the signal wirings 24, and a ground circuit 25. The ground circuit 25 is an example of a conductor circuit 30. The ground circuit 25 has openings 251, and the signal wirings 24 are formed in the openings 251. The ground circuit 25 is a continuous pattern (solid pattern). The uppermost conductor layer 20 can have multiple ground circuits (25x, 25y, 25z). These are examples of equipotential circuits. In FIG. 1, the ground circuit (first ground circuit) (25x) is an example of a first conductor circuit 31, the ground circuit (second ground circuit) (25y) is an example of a second conductor circuit 32, and the ground circuit (third ground circuit) (25z) is an example of a third conductor circuit 33. The signal wirings 24 may be formed between the first conductor circuit 31 and the second conductor circuit 32. When the uppermost conductor layer 20 includes a power supply circuit, the ground circuit in FIG. 1 is replaced with the power supply circuit.

An electronic component is mounted on the printed wiring board 2 via the electrodes 22. The multiple electrodes 22 are formed in a mounting area 4 for mounting an electronic component.

The solder resist layer 40 is formed on the uppermost resin insulating layer 10 and the uppermost conductor layer 20. The solder resist layer 40 has multiple openings 50 and multiple openings 60 that penetrate the solder resist layer 40. The openings 50 are first openings. The openings (first openings) 50 are openings for exposing the electrodes 22 and penetrate the solder resist layer 40 to reach the electrodes 22. The openings 60 are second openings. The openings (second openings) 60 are openings for exposing the conductor circuit 30 and penetrate the solder resist layer 40 to reach the conductor circuit 30. The second openings 60 also serve as openings for the dam conductors 70. In the embodiment, the second openings 60 reach the ground circuit 25. In this case, the second openings 60 expose the ground circuit 25. It is preferable that there are multiple second openings 60 reaching one conductor circuit 30. Each equipotential circuit is exposed by multiple openings 60. When the uppermost conductor layer 20 includes a ground circuit, multiple second openings 60 reach one ground circuit. When the uppermost conductor layer 20 includes a power supply circuit, multiple second openings 60 reach one power supply circuit. When the uppermost conductor layer 20 has multiple conductor circuits (equipotential circuits) that have substantially the same potential, the second openings 60 are formed for each of the equipotential circuits. Examples of the equipotential circuits include the first conductor circuit 31 and the second conductor circuit 32. It is preferable that the multiple second openings 60 reach each of the equipotential circuits. When the uppermost conductor layer 20 includes multiple ground circuits, the openings 60 are formed for each of the ground circuits. It is preferable that there are multiple openings 60 reaching one ground circuit. When the uppermost conductor layer 20 includes multiple power supply circuits, the openings 60 are formed for each of the power supply circuits. It is preferable that there are multiple openings 60 reaching one power supply circuit. When equipotential circuits are present, the second openings 60 include first equipotential circuit openings 61 reaching the first conductor circuit 31 and second equipotential circuit openings 62 reaching the second conductor circuit 32. Further, the second openings 60 may include third equipotential circuit openings 63 reaching the third conductor circuit 33. The first equipotential circuit openings 61 may be referred to as openings 61. The second equipotential circuit openings 62 may be referred to as openings 62. The third equipotential circuit openings 63 may be referred to as openings 63. The openings 61 expose the first conductor circuit 31. The openings 62 expose the second conductor circuit 32. The openings 63 expose the third conductor circuit 33. There are multiple openings 61, multiple openings 62, and multiple openings 63. The number of the openings 61 and the number of the openings 62 are different. The number of the openings 61 and the number of the openings 63 are different. The number of the openings 61 and the number of the openings 62 may be the same. The number of the openings 61 and the number of the openings 63 may be the same. A size of each of the first openings 50 and a size of each of the second openings 60 are equal. Or, the size of each of the second openings 60 is larger than the size of each of the first openings 50. A shape of each of the openings 61 and a shape of each of the openings 62 may be substantially the same. The shape of each of the openings 61 and a shape of each of the openings 63 may be substantially the same.

The metal dam 80 prevents outflow of an underfill material. The metal dam 80 is formed on the solder resist layer 40 and the dam conductors 70. The metal dam 80 substantially surrounds the mounting area 4. The metal dam 80 is mainly formed of copper. The metal dam 80 is formed of a seed layer (80a) and an electrolytic plating layer (80b) on the seed layer (80a). The seed layer (80a) forming the metal dam 80 is similar to the seed layer (20a) forming the uppermost conductor layer 20. The electrolytic plating layer (80b) forming the metal dam 80 is similar to the electrolytic plating layer (20b) forming the uppermost conductor layer 20.

The dam conductors 70 are formed in the openings (second openings) 60. The metal dam 80 is connected to the conductor circuit 30 via the dam conductors 70. The dam conductors 70 connecting the metal dam 80 and the conductor circuit 30 are positioned directly below the metal dam 80. The conductor circuit 30 connected to the metal dam 80 is positioned directly below the metal dam 80. In the embodiment, the metal dam 80 is connected to the ground circuit 25 via the dam conductors 70. It is also possible that the metal dam 80 is connected to a power supply circuit via the dam conductors 70. When the conductor circuit 30 has the first conductor circuit 31 and the second conductor circuit 32, the dam conductors 70 include first dam conductors 71 formed in the openings 61 and second dam conductors 72 formed in the openings 62. When the conductor circuit 30 further includes the third conductor circuit 33, the dam conductors 70 include third dam conductors 73 formed in the openings 63. The metal dam 80 is connected to the first conductor circuit 31 via the first dam conductors 71. The metal dam 80 is connected to the second conductor circuit 32 via the second dam conductors 72. The metal dam 80 is connected to the third conductor circuit 33 via the third dam conductors 73. In this way, the one metal dam 80 is connected to multiple equipotential circuits. The one metal dam 80 is connected to the equipotential circuits via the multiple dam conductors 70. The dam conductors 70 are primarily formed of copper. The dam conductors 70 are formed of a seed layer (80a) and an electrolytic plating layer (80b) on the seed layer (80a). The seed layer (80a) forming the metal dam 80 and the seed layer (80a) forming the dam conductors 70 are common. The electrolytic plating layer (80b) forming the metal dam 80 and the electrolytic plating layer (80b) forming the dam conductors 70 are common. The dam conductors 70 are formed at the same time as the metal dam 80. The metal dam 80 and the dam conductors 70 are integrally formed. The metal dam 80 and all the dam conductors 70 are integrally formed. In the embodiment, the metal dam 80 is connected to the ground circuit 25 via the dam conductors 70. The metal dam 80 and the conductor circuit 30 are connected by the dam conductors 70. The metal dam 80 is strongly bonded to a ground circuit via the dam conductors 70. It is also possible that the metal dam 80 is bonded to a power supply circuit via the dam conductors 70. In this case, the metal dam 80 is strongly bonded to the power supply circuit via the dam conductors 70. Since the conductor circuit 30 is covered by the solder resist layer 40, the metal dam 80 connected to the conductor circuit 30 is unlikely to detach from the printed wiring board 2.

When the metal dam 80 is formed with multiple sides, it is preferable that the sides are each connected to a ground circuit or a power supply circuit via the dam conductors 70. The sides are preferably each connected to a ground circuit or a power circuit via the multiple dam conductors 70. The dam 80 in FIG. 1 is formed with four sides (81x, 81y, 81z, 81w). The sides may each be connected to one ground circuit or one power supply circuit via the dam conductors 70. The sides may be respectively connected to equipotential circuits via the dam conductors 70. The sides may be respectively connected to different equipotential circuits via the dam conductors 70. The metal dam 80 is unlikely to peel off from the upper surface of the solder resist layer 40.

In the printed wiring board 2 of the embodiment, the metal dam 80 is connected to the first ground circuit (25x) via the first dam conductors 71. The metal dam 80 is connected to the second ground circuit (25y) via the second dam conductors 72. The metal dam 80 is connected to the third ground circuit (25z) via the third dam conductors 73. The one metal dam 80 is connected to at least one conductor circuit 30 via the multiple dam conductors 70. Therefore, the metal dam 80 is unlikely to peel off from the upper surface of the solder resist layer 40. The metal dam 80 does not shrink upon curing. Or, an amount of shrinkage of the metal dam 80 is smaller than that of a resin. The metal dam 80 has higher strength than a resin dam. The printed wiring board 2 is unlikely to warp. A high-quality printed wiring board 2 can be obtained.

### Method for Manufacturing Printed Wiring Board

An intermediate substrate including the uppermost resin insulating layer 10 and the uppermost conductor layer 20 is prepared. The uppermost conductor layer 20 has the electrodes 22, signal wirings 24 and ground circuit 25 for mounting an electronic component. The ground circuit 25 includes the first ground circuit (25x), the second ground circuit (25y), and the third ground circuit (25z). The first ground circuit (25x), the second ground circuit (25y), and the third ground circuit (25z) are examples of equipotential circuits. The solder resist layer 40 is formed on the uppermost resin insulating layer 10 and the uppermost conductor layer 20. The multiple openings (50, 60) penetrating the solder resist layer 40 are formed. The openings (50, 60) are formed using laser. The openings (first openings) 50 expose the electrodes 22. The openings (second openings) 60 expose the ground circuit 25. The openings 60 include the multiple openings 61, the multiple openings 62, and the multiple openings 63. The openings 61 expose the first ground circuit (25x). The openings 62 expose the second ground circuit (25y). The openings 63 expose the third ground circuit (25z). The size of each of the openings 50 and the size of each of the openings 60 are equal. Or, the size of each of the openings 60 is larger than the size of each of the openings 50. The size of each of the openings 61 and the size of each of the openings 62 may be different. It is preferable that the size of each of the openings 61 is larger than the size of each of the openings 62. The sizes of the openings (50, 60) are measured on the upper surface of the solder resist layer 40 (the surface away from the uppermost resin insulating layer 10). A planar shape of each of the openings (50, 60) on the upper surface of the solder resist layer 40 is substantially circular. The size of each of the openings (50, 60) is represented by a diameter on the upper surface of the solder resist layer 40.

The seed layer (80a) is formed on the solder resist layer 40, on inner wall surfaces of the openings (50, 60), on the electrodes 22 exposed from the openings 50, and on the ground circuit 25 exposed from the openings 60. A plating resist is formed on the seed layer (80a). The plating resist has openings for forming the metal dam 80 and the dam conductors 70. The electrolytic plating layer (80b) is formed on the seed layer (80a) exposed from the plating resist. The electrolytic plating layer (80b) fills the openings 60. The electrolytic plating layer (80b) is formed on the solder resist layer 40. The dam conductors 70 and the metal dam 80 are formed. These are formed at the same time. The dam conductors 70 are formed of the seed layer (80a) in the openings 60 and the electrolytic plating layer (80b) on the seed layer (80a). The metal dam 80 includes a portion formed by the seed layer (80a) on the solder resist layer 40 and the electrolytic plating layer (80b) on the seed layer (80a) (portion on the solder resist layer), and a portion formed by the electrolytic plating layer (80b) on the dam conductors 70 (portion on the dam conductors). The metal dam 80 and the dam conductors 70 are continuous. The metal dam 80 and the dam conductors 70 are integrally formed. The dam conductors 70 connect the ground circuit 25 and the metal dam 80. The first dam conductors 71 are formed in the openings 61. The second dam conductors 72 are formed in the openings 62. The third dam conductors 73 are formed in the openings 63. The first dam conductors 71 connect the first ground circuit (25x) and the metal dam 80. The second dam conductors 72 connect the second ground circuit (25y) and the metal dam 80. The third dam conductors 73 connect the third ground circuit (25z) and the metal dam 80. The plating resist is removed. The seed layer (80a) exposed from the electrolytic plating layer (80b) is removed. The printed wiring board 2 of the embodiment is obtained.

### Alternative Example

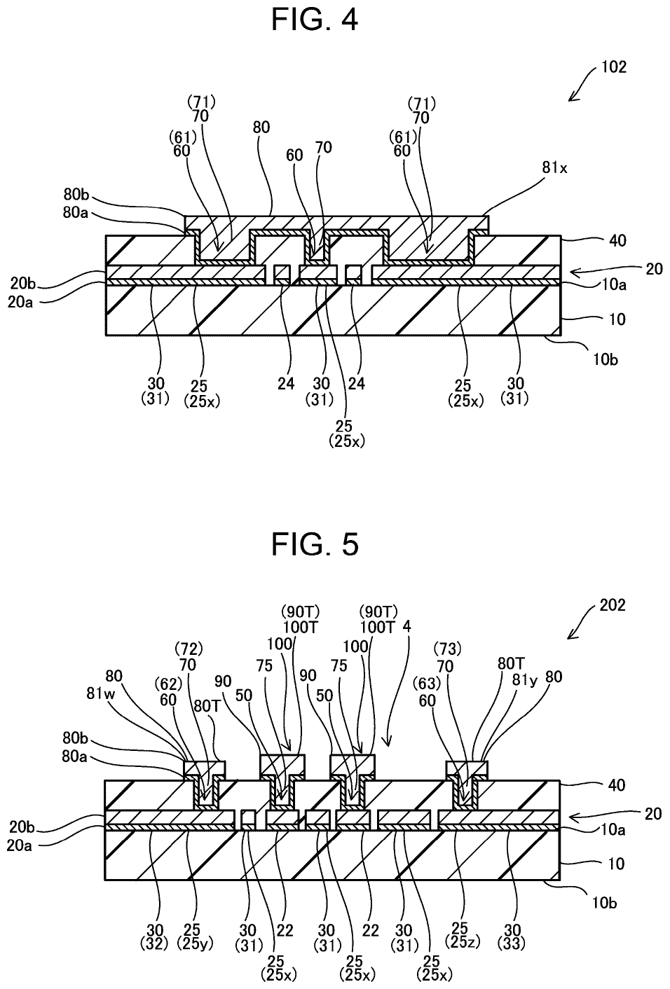

FIG. 4 illustrates a cross-sectional view of a printed wiring board 102 of an alternative example according to an embodiment of the present invention. FIG. 4 corresponds to a cross-sectional view between II-II in FIG. 1. The embodiment and the alternative example are different in the planar shapes of the openings 60. The planar shapes of the openings 50 and the openings 60 are observed on the upper surface of the solder resist layer 40. The size of each of the openings 50 is represented by an area of the planar shape of each of the openings 50. The size of each of the openings 60 is represented by an area of the planar shape of each of the openings 60. The planar shape of each of the openings 50 of the embodiment and the planar shape of each of the openings 50 of the alternative example of the embodiment are substantially circular. The planar shape of each of the openings 60 of the embodiment is substantially circular. In contrast, the alternative example has openings 60 that each have a substantially elliptical planar shape. Or, the alternative example has openings 60 that each have a substantially rectangular planar shape. The alternative example may have openings 60 that each have a substantially elliptical planar shape and openings 60 that each have a substantially rectangular planar shape. The alternative example may have openings 60 that each have a substantially circular planar shape and openings 60 that each have a substantially rectangular planar shape. The alternative example may have openings 60 that each have a substantially circular planar shape and openings 60 that each have a substantially circular planar shape. In the alternative example, the size of each of the openings 60 is larger than the size of each of the openings 50. The size of each of the openings 60 is larger than the size of each of the openings 50. The size of each of the openings 62 is larger than the size of each of the openings 50. The planar shape of each of the openings 61 is substantially elliptical or substantially rectangular. The planar shape of each of the openings 62 is substantially elliptical or substantially rectangular. The shape of each of the openings 61 and the shape of each of the openings 62 are substantially the same. In the alternative example of the embodiment, the planar shape of each of the openings 60 is substantially elliptical.

Comparing the embodiment and the alternative example, the size of each of the openings 60 of the alternative example is larger than the size of each of the openings 60 of the embodiment. Therefore, the alternative example can increase bonding strength between the metal dam 80 and the ground circuit 25. The metal dam 80 is even more unlikely to peel off from the upper surface of the solder resist layer 40.

### Method for Manufacturing Printed Wiring Board of Alternative Example

A manufacturing method of the alternative example and the manufacturing method of the embodiment are the same except for the method for forming the openings 60. In the alternative example, laser is irradiated onto the solder resist layer 40 such that the planar shape of each of the openings 60 is substantially elliptical or substantially rectangular. In the alternative example of the embodiment, the planar shape of each of the openings 60 is substantially elliptical. Openings 60 each having a substantially elliptical planar shape, openings 60 each having a substantially rectangular planar shape, and openings 60 each having a substantially circular planar shape may coexist. It is preferable that openings 60 each having a substantially elliptical planar shape, and openings 60 each having a substantially circular planar shape coexist. Or, it is preferable that openings 60 each having a substantially rectangular planar shape, and openings 60 each having a substantially circular planar shape coexist.

### Modified Example

FIG. 5 illustrates a cross-sectional view of a printed wiring board 202 of a modified example according to an embodiment of the present invention. FIG. 5 corresponds to a cross-sectional view between III-III in FIG. 1. As illustrated in FIG. 5, the printed wiring board 202 of the modified example has metal posts 100 on the electrodes 22. The printed wiring board 202 of the modified example is formed by adding the metal posts 100 to the printed wiring board 2 of the embodiment. Or, the printed wiring board 202 of the modified example is formed by adding the metal posts 100 to the printed wiring board 102 of the alternative example of the embodiment. The metal posts 100 are each composed of a via conductor 75 and a post 90, the via conductors 75 being respectively formed in the openings 50 and the posts 90 being respectively formed on the via conductors 75. The posts 90 protrude from the upper surface of the solder resist layer 40. The posts 90 are each formed of a portion that is directly on a via conductor 75 and a portion that is on the solder resist layer 40 around an opening 50. The via conductors 75 are respectively integrally formed with the posts 90. The via conductors 75 are respectively continuous with the posts 90. The via conductors 75 respectively connect the electrodes 22 to the posts 90. An electronic component is mounted on the printed wiring board 202 via the metal posts 100.

The metal posts 100 are mainly formed of copper. The metal posts 100 are formed of a seed layer (80a) and an electrolytic plating layer (80b) on the seed layer (80a). The seed layer (80a) forming the metal dam 80 and the dam conductors 70 and the seed layer (80a) forming the metal posts 100 are common. The electrolytic plating layer (80b) forming the metal dam 80 and the dam conductors 70 and the electrolytic plating layer (80b) forming the metal posts 100 are common. The metal posts 100 and the metal dam 80 are formed at the same time. The posts 90 and the metal dam 80 are formed at the same time. The via conductors 75 and the dam conductors 70 are formed at the same time.

As illustrated in FIG. 5, a height of an upper surface (80T) of the metal dam 80 and a height of an upper surface (100T) of each of the metal posts 100 are different. In FIG. 5, the upper surface (100T) of each of the metal posts 100 is higher than the upper surface (80T) of the metal dam 80. It is also possible that the upper surface (80T) of the metal dam 80 is higher than the upper surface (100T) of each of the metal posts 100. A distance between the upper surface (100T) of each of the metal posts 100 and the upper surface (80T) of the metal dam 80 (a difference in height between the two) is 3 μm or more and 15 μm or less. The difference in height between the two is preferably 5 μm or more and 12 μm or less.

The printed wiring board 202 of the modified example has the metal posts 100 in the mounting area 4. An electronic component is mounted on the printed wiring board 202 via the metal posts 100. Even when the printed wiring board 202 has the metal dam 80, the modified example allows an electronic component to be easily mounted on the printed wiring board 202. The metal dam 80 is unlikely to interfere with the mounting. The modified example can increase the connection reliability between the electronic component and the printed wiring board 202.

### [Method for Manufacturing the Printed Wiring Board 202 of the Modified Example]

An intermediate substrate having the openings 50 and the openings 60 is formed using a method similar to the manufacturing method of the embodiment. Or, an intermediate substrate having the openings 50 and the openings 60 is formed using a method similar to the manufacturing method of the alternative example of the embodiment. Therefore, the printed wiring board 202 of the modified example has the openings 50 and openings 60 similar to those in the embodiment. Or, the printed wiring board 202 of the modified example has the openings 50 and openings 60 similar to those in the alternative example of the embodiment. Therefore, the planar shape of each of the openings 50 in the printed wiring board 202 of the modified example is substantially circular. The planar shape of each of the openings 60 in the printed wiring board 202 of the modified example is selected from substantially circular, substantially elliptical, and substantially rectangular. The seed layer (80a) is formed on the solder resist layer 40, on inner wall surfaces of the openings (50, 60), on the electrodes 22 exposed from the openings 50, and on the ground circuit 25 exposed from the openings 60. A plating resist is formed on the seed layer (80a). The plating resist has openings for forming the metal dam 80, the dam conductors 70, and the metal posts 100. The electrolytic plating layer (80b) is formed on the seed layer (80a) exposed from the plating resist. The electrolytic plating layer (80b) fills the openings (50, 60). The metal dam 80 having elements similar to those in the embodiment is formed. The metal posts 100 formed of the seed layer (80a) and the electrolytic plating layer (80b) on the seed layer (80a) are formed. The metal posts 100 and the metal dam 80 are formed at the same time.

The plating resist is removed. The seed layer (80a) exposed from the electrolytic plating layer (80b) is removed. The printed wiring board 202 of the modified example is obtained.

When the electrolytic plating layer (80b) is formed, a magnitude of a current for forming the metal dam 80 and a magnitude of a current for forming the posts 90 are controlled. For example, a magnitude of a current is controlled using a shielding plate. The modified example controls a thickness of the electrolytic plating layer (80b) forming the metal dam 80 and a thickness of the electrolytic plating layer (80b) forming the posts 90. The thickness of the electrolytic plating layer (80b) forming the metal dam 80 is larger than the thickness of the electrolytic plating layer (80b) forming the posts 90. Or, the thickness of the electrolytic plating layer (80b) forming the metal dam 80 is smaller than the thickness of the electrolytic plating layer (80b) forming the posts 90. Therefore, a height of an upper surface (90T) of each of the posts 90 and a height of the upper surface (80T) of the metal dam 80 are different. The upper surface (90T) of each of the posts 90 is higher than the upper surface (80T) of the metal dam 80. In other examples, the upper surface (80T) of the metal dam 80 is higher than the upper surface (90T) of each of the posts 90. Since the height of each of the metal posts 100 and the height of the metal dam 80 are substantially equal, the printed wiring board 202 of the modified example can increase connection strength between the metal posts 100 and the electronic component. Even when the printed wiring board 202 is subjected to an impact, the connection reliability between the metal posts 100 and the electronic component is likely to remain stable for a long period of time.

Japanese Patent Application Laid-Open Publication No. 2014-96558 describes a printed wiring board having a base substrate and a dam formed on the base substrate. The dam is formed by applying dam ink onto the base substrate using an inkjet method and curing the dam ink.

It is thought that when wettability of an upper surface of the base substrate is poor, the dam ink and the upper surface of the base substrate may not sufficiently adhere to each other. It is thought that the dam may peel off from the base substrate. It is thought that the dam is formed only on the upper surface of the base substrate. It is thought that the base substrate may warp due to curing shrinkage of the dam ink.

A printed wiring board according to an embodiment of the present invention includes: an uppermost resin insulating layer; an uppermost conductor layer that is formed on the uppermost resin insulating layer and includes multiple electrodes and a conductor circuit for mounting an electronic component; a solder resist layer that is formed on the uppermost resin insulating layer and the uppermost conductor layer, and has multiple first openings reaching the electrodes and at least one second opening reaching the conductor circuit; at least one dam conductor that is formed in the at least one second opening; and a metal dam that is formed on the solder resist layer and the at least one dam conductor. The multiple electrodes are formed in a mounting area for mounting the electronic component. The metal dam substantially surrounds the mounting area. The conductor circuit is a ground circuit or a power supply circuit. The metal dam is connected to the conductor circuit via the at least one dam conductor.

In a printed wiring board according to an embodiment of the present invention, the metal dam is connected to the conductor circuit via the at least one dam conductor. Therefore, the metal dam is unlikely to peel off from the upper surface of the solder resist layer. The metal dam does not shrink upon curing. Or, an amount of shrinkage of the metal dam is very small. The metal dam has higher strength than a resin dam. The printed wiring board is unlikely to warp. A high-quality printed wiring board can be obtained.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
an uppermost resin insulating layer;
an uppermost conductor layer formed on the uppermost resin insulating layer;
a solder resist layer formed on the uppermost resin insulating layer such that the solder resist layer is covering the uppermost conductor layer;
a dam conductor formed in the solder resist layer such that the dam conductor is connected to the upper most conductor layer; and
a metal dam formed on the solder resist layer such that the metal dam is formed on and connected to the dam conductor,
wherein the uppermost conductor layer includes a plurality of electrodes and a conductor circuit such that the electrodes and conductor circuit are positioned to mount an electronic component in a mounting area in the solder resist layer and that the metal dam is surrounding the mounting area of the solder resist layer, the solder resist layer is formed such that the solder resist layer has a plurality of first openings reaching to the electrodes of the uppermost conductor layer and a second opening reaching to the conductor circuit of the uppermost conductor layer and that the dam conductor is formed in the second opening of the solder resist layer, and the conductor circuit in the uppermost conductor layer is a ground circuit or a power supply circuit such that the conductor circuit is connected to the metal dam via the dam conductor.

2. The printed wiring board according to claim 1, wherein the solder resist layer is formed such that the second opening is formed in a plurality and that the plurality of second openings is reaching the conductor circuit in the uppermost conductor layer.

3. The printed wiring board according to claim 2, wherein the conductor circuit in the uppermost conductor layer includes a first conductor circuit and a second conductor circuit having a same potential as the first conductor circuit, the plurality of second openings formed in the solder resist layer includes a first equipotential circuit opening reaching to the first conductor circuit and a second equipotential circuit opening reaching to the second conductor circuit, and the dam conductor is formed in a plurality such that the plurality of dam conductor includes a first dam conductor formed in the first equipotential circuit opening and a second dam conductor formed in the second equipotential circuit opening and that the metal dam is connected to the first conductor circuit via the first dam conductor and to the second conductor circuit via the second dam conductor.

4. The printed wiring board according to claim 3, wherein the first equipotential circuit opening is formed in a plurality, and the second equipotential circuit opening is formed in a plurality.

5. The printed wiring board according to claim 3, wherein the uppermost conductor layer includes a signal wiring formed between the first conductor circuit and the second conductor circuit.

6. The printed wiring board according to claim 1, wherein the solder resist layer is formed such that a size of the second opening is equal to or larger than a size of each of the first openings.

7. The printed wiring board according to claim 6, wherein the size of the second opening is larger than the size of each of the first openings, and the second opening has a planar shape that is elliptical or rectangular.

8. The printed wiring board according to claim 3, wherein the solder resist layer is formed such that a size of the second opening is equal to or larger than a size of each of the first openings.

9. The printed wiring board according to claim 8, wherein the size of the second opening is larger than the size of each of the first openings, and the second opening has a planar shape that is elliptical or rectangular.

10. The printed wiring board according to claim 8, wherein the size of the second opening is larger than the size of each of the first openings, the second opening has a shape that is elliptical or rectangular, and the first equipotential circuit opening and the second equipotential circuit opening has a same shape.

11. The printed wiring board according to claim 1, further comprising:
a plurality of metal posts configured to mount the electronic component such that each of the metal posts includes a via conductor formed in a respective one of the first openings in the solder resist layer and a post formed on the via conductor and protruding from a surface of the solder resist layer.

12. The printed wiring board according to claim 11, wherein the metal dam and the metal posts are formed in a same process.

13. The printed wiring board according to claim 11, wherein the via conductor of each of the metal posts and the dam conductor are formed in a same process.

14. The printed wiring board according to claim 11, wherein the plurality of metal posts is formed such that a height of an upper surface of the metal dam and a height of an upper surface of each of the metal posts are different.

15. The printed wiring board according to claim 4, wherein the solder resist layer is formed such that a number of the first equipotential circuit openings and a number of the second equipotential circuit openings are different.

16. The printed wiring board according to claim 2, further comprising:
a plurality of metal posts configured to mount the electronic component such that each of the metal posts includes a via conductor formed in a respective one of the first openings in the solder resist layer and a post formed on the via conductor and protruding from a surface of the solder resist layer.

17. The printed wiring board according to claim 16, wherein the plurality of metal posts is formed such that a height of an upper surface of the metal dam and a height of an upper surface of each of the metal posts are different.

18. The printed wiring board according to claim 4, wherein the solder resist layer is formed such that a number of the first equipotential circuit openings and a number of the second equipotential circuit openings are different.

19. The printed wiring board according to claim 2, wherein the solder resist layer is formed such that a size of the second opening is equal to or larger than a size of each of the first openings.

20. The printed wiring board according to claim 19, wherein the size of the second opening is larger than the size of each of the first openings, and the second opening has a planar shape that is elliptical or rectangular.
